(19) United States
(12) Patent Application Publication
(10) Pub. No.: US 2015/0262985 A1
(43) Pub. Date: Sep. 17, 2015

(54) PHOTORELAY

(71) Applicant: KABUSHIKI KAISHA TOSHIBA, Tokyo (JP)

(72) Inventors: Naoya TAKAI, Yukuhashi Fukuoka (JP); Mami YAMAMOTO, Nakatsu Oita (JP); Yoshio NOGUCHI, Komatsu Ishikawa (JP); Eiji NAKASHIMA, Kurate Fukuoka (JP)

(21) Appl. No.: 14/474,042

(22) Filed: Aug. 29, 2014

(30) Foreign Application Priority Data
Mar. 14, 2014 (JP) 2014-052675

(51) Int. Cl. H01L 25/16; H01L 29/78; H01L 31/16; H01L 23/31; H01L 23/538

(52) U.S. Cl. CPC H01L 25/167; H01L 25/165; H01L 23/3107; H01L 23/5386; H01L 31/16; H01L 29/78

(57) ABSTRACT

A photorelay includes an insulation board, input and output terminals, a die pad portion, a light receiving element, a light emitting element, a MOSFET, and a first sealing resin layer. The insulation board has first and second surfaces. The input terminal includes a first conductive region. The output terminal includes a first conductive region. The light receiving element is bonded on the die pad portion. The light emitting element is bonded on an exposed surface of the light receiving element, and connected to the first conductive region of the input terminal. The MOSFET is connected to the first conductive region of the output terminal. A connecting electrode is included as a part of the input or output terminal. Attachment conductive regions included respectively in the input and output terminals are provided on a side surface of the insulation board as the attachment surface of the photorelay to a wiring substrate.

### CROSS-REFERENCE TO RELATED APPLICATION

This application is based upon and claims the benefit of priority from Japanese Patent Application No. 2014-052675, filed Mar. 14, 2014, the entire contents of which are incorporated herein by reference.

### FIELD

Embodiments described herein relate generally to a photorelay.

### BACKGROUND

Photorelays including an optically-coupled isolation circuit transform an input electrical signal into a light signal by a light emitting element, receive the light with a light receiving element, and thereafter output an electrical signal. Thereby, an optically-coupled device is capable of transmitting electrical signals, while the input and the output of the optically-coupled device are isolated from each other.

A large number of photorelays for an alternating current load are used in a semiconductor tester for testing semiconductor integrated circuits and the like. Further, when a high speed DRAM or the like is evaluated, switching high frequency signals of 1 GHz or more are required.

The photorelay includes an output circuit capable of switching signals by a MOSFET in response to the turning ON and OFF of the input electrical signals. Thereby, when mounted on the mounting board of the semiconductor tester, the photorelay is required to have a configuration capable of maintaining good high frequency characteristics.

### DESCRIPTION OF THE DRAWINGS

FIG. 1A is a schematic perspective view of a photorelay according to a first embodiment.

FIG. 1B is a schematic cross-sectional view taken along line A-A of FIG. 1A.

FIG. 1C is a schematic perspective view of the photorelay before sealing the photorelay in a resin.

FIG. 2 is a schematic perspective view of a mounting member of the photorelay of the first embodiment.

FIG. 3 is a configuration diagram of the photorelay according to the first embodiment.

FIG. 4 is a graph chart illustrating transmission loss dependency of the photorelay of the first embodiment on frequency.

FIG. 5A illustrates one example of a diagram of a measurement circuit for measuring transmission loss.

FIG. 5B illustrates a schematic cross-sectional view of the measurement circuit of FIG. 5A attached to an external circuit board.

FIG. 6A is a partial schematic plan view of the photorelay according to a variant example of the first embodiment.

FIG. 6B is a graph chart illustrating transmission loss dependency of the photorelay of FIG. 6A on frequency.

FIG. 7A is a schematic plan view of a photorelay according to a second embodiment.

FIG. 7B is a schematic side view of the photorelay according to the second embodiment.

FIG. 8A is a schematic side view of the photorelay according to the second embodiment, attached to an external circuit board.

FIG. 8B is a schematic back view of the photorelay according to the second embodiment.

FIG. 9 is a schematic cross-sectional view of a photorelay according to a third embodiment, which is attached to an external circuit board.

FIG. 10 is a schematic cross-sectional view of a photorelay according to a fourth embodiment, which is attached to an external circuit board.

### DETAILED DESCRIPTION

Embodiments provide a photorelay capable of reduced transmission loss otherwise caused by the parasitic capacitance between a MOSFET and an external circuit board.

In general, according to one embodiment, a photorelay according to an embodiment includes an insulation board, an input terminal, an output terminal, a die pad portion, a light receiving element, a light emitting element, a MOSFET, and a first sealing resin layer. The photorelay has a side surface serving as an attachment surface to connect the photorelay to an external circuit board. The insulation board includes a first surface and a second surface opposite to the first surface. The input terminal includes a first conductive region on the first surface. The output terminal includes a first conductive region on the first surface. The die pad portion is provided on the first surface between the input terminal and the output terminal. The light receiving element is bonded on the die pad portion such as with an adhesive. The light emitting element is bonded on a top surface of the light receiving element with an adhesive which need not be conductive, and is connected to the first conductive region of the input terminal. The MOSFET is connected to the first conductive region of the output terminal. The first sealing resin layer covers the light receiving element, the light emitting element, the MOSFET, and the first surface. A connecting electrode is included in either the input terminal or the output terminal. An attachment conductive region included in the input terminal and an attachment conductive region included in the output terminal are provided on the side surface used as the attachment surface of the insulation board.

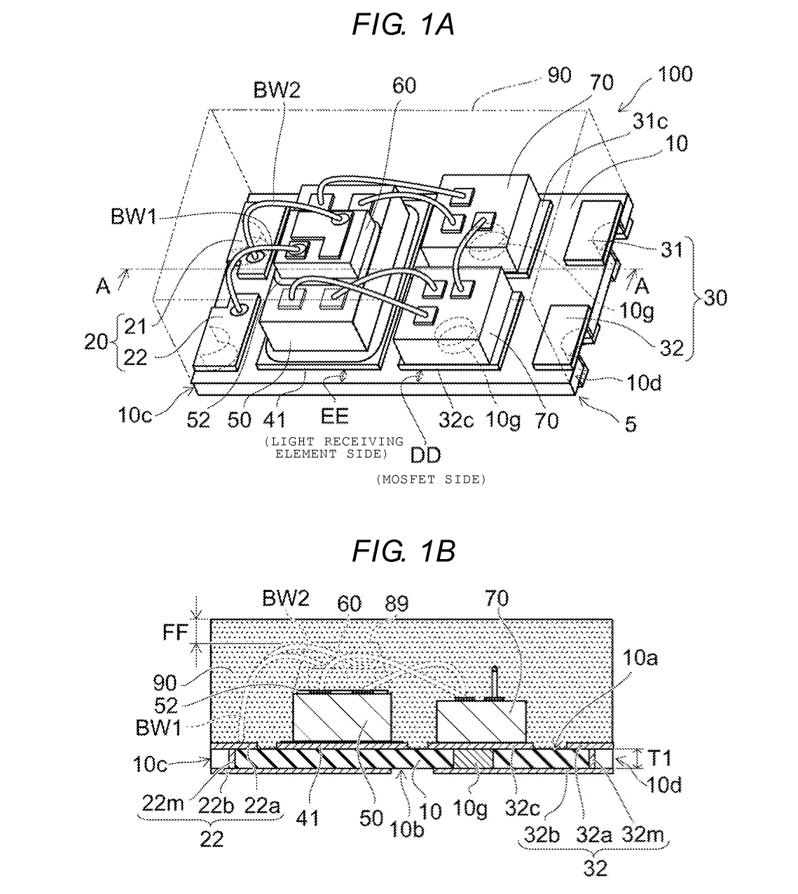

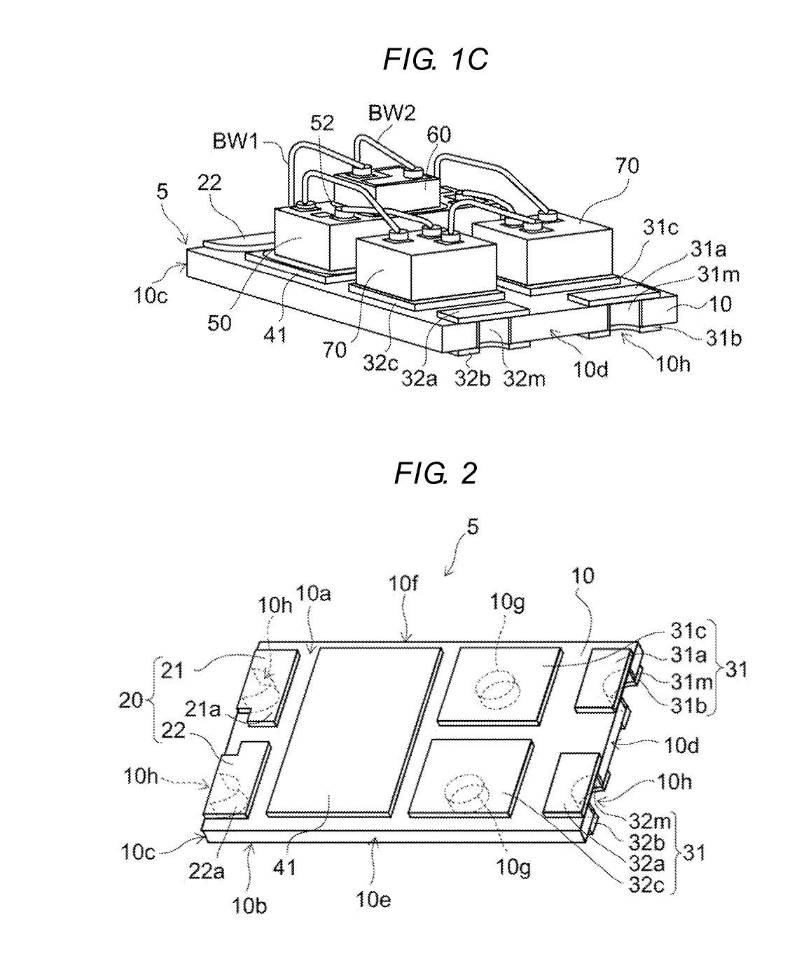

Hereinafter, embodiments will be described with reference to drawings. FIG. 1A is a schematic perspective view of a photorelay according to a first embodiment. FIG. 1B is a schematic cross-sectional view taken along line A-A of FIG. 1A. FIG. 1C is a schematic perspective view of the photorelay of the first embodiment before being sealed in resin.

The photorelay 100 includes a mounting member 5, MOSFETs 70 bonded on output terminals 30 (31, 32) of the mounting member 5 by a conductive adhesive or solder, a light receiving element 50 bonded to a die pad portion 41 by an adhesive and having a light receiving surface on the top surface thereof, a light emitting element 60 for irradiating the light receiving surface with light, an adhesion layer 52 having optically transmissive and insulative properties and bonding the light-emitting element 60 on the top surface of the light receiving element 50, and a sealing resin layer 90 shown in phantom. The light emitting element 60 is, for example, a Light Emitting Diode (LED) or the like. Also, the light receiving element 50 may be a photodiode, a phototransistor, a light receiving IC, or the like.

In the present drawings, the MOSFETs 70 include two MOSFET elements connected in a common source configuration. Note that the exemplary embodiment is not limited thereto, and may include one MOSFET. Where a chip back surface of each MOSFET 70 is a drain, the output terminals 31, 32 are connected to the drains of the respective MOSFETs.

The sealing resin layer 90 covers, and protects the inside of, the light receiving element 50, the light emitting element 60, and a first surface 10a of an insulation board 10.

FIG. 2 is a schematic perspective view of the mounting member. The mounting member 5 includes an insulation board 10, input terminals 20 (21, 22), output terminals 30, and a die pad portion 41 provided on a region of the first surface 10a between the input terminals 20 and the output terminals 30.

The insulation board 10 includes a rectangular first surface 10a, a second surface 10b on the opposite side to the first surface 10a, a first side surface 10c, a second side surface 10d which is opposite to the first side surface 10c, a third side surface 10e, and a fourth side surface 10f which is opposite to the third side surface 10e. Also, through holes 10g from the first surface 10a to the second surface 10b are further provided. The insulation board 10 is made of fiberglass or the like, and has a thickness T1 of 0.3 mm or more.

Also, cutout portions 10h are provided on the first side surface 10c and the second side surface 10d of the insulation board 10. Conductive regions extend along the inner walls of the cutout portions 10h.

The input terminals 20 include, for example, two terminals 21, 22. In the respective terminals 21, 22, first conductive regions 21a, 22a provided on the first surface 10a are connected to second conductive regions 21b (not illustrated), 22b provided on the second surface 10b as shown in FIG. 1B, via first conductive regions 21m (not illustrated), 22m provided on the first side surface 10c as shown in FIG. 1B, respectively. By bonding the conductive regions of the first side surface 10c and wiring members such as the external circuit board or the like with solder or the like, joining condition of the solder material may be easily checked.

Likewise, the output terminals 30 include, for example, two terminals 31, 32. In the respective terminals 31, 32, first conductive regions 31a, 32a provided on the first surface 10a are connected to second conductive regions 31b, 32b provided on the second surface 10b, via conductive regions 31m, 32m provided on the cutout portions 10h.

As illustrated in FIG. 1A, by providing through holes 10g in the insulation board 10, the first conductive regions 31a, 32a of the output terminals 30 are connected to third conductive regions 31c, 32c, by conductive paste layers filled in the inside of the through holes 10g, side wall conductive regions, or the like. The output terminals 30 are insulated from the input terminals 20 by the board 10.

The input terminals 20, the output terminals 30, and the die pad portion 41 may be made of copper foils provided on the surface of the insulation board 10, plated layers of Ni, Au or the like deposited on the copper foils, and others. Also, as seen from above, the input terminals 20, the output terminals 30, and the die pad portion 41 are spaced from each other, and are insulated from each other, on the insulation board 10.

Also, as illustrated in FIG. 1C, by providing the cutout portions 10h on the side surfaces 10c, 10d of the insulation board 10, the second conductive regions (31m, 32m and the like) can be provided on the inner walls of the cutout portions 10h by plating.

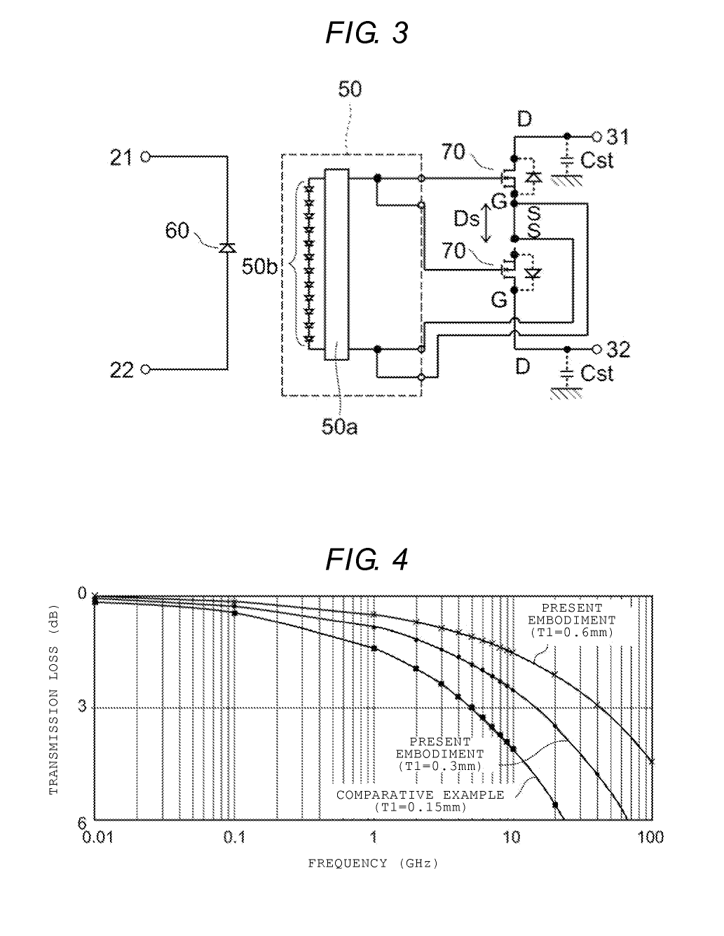

FIG. 3 is a configuration diagram of the photorelay according to the first embodiment. The light receiving element 50 further includes a control circuit 50a. The control circuit 50a is connected to each of a first electrode and a second electrode of a photodiode array 50b. In this configuration, the voltage is supplied to each gate of the MOSFETs 70 connected in common source configuration. Also, the control circuit 50a includes a resistor or the like to cause an electrical discharge when the MOSFETs 70 turn from ON to OFF, in order to shorten the fall-down time.

The MOSFETs 70 are, for example, of n-channel enhancement type. In FIG. 3, the gates G of the MOSFETs 70 are connected to the anode of the photodiode 50b. Also, the respective sources S are connected to the cathode of the photodiode 50b, and the respective drains D are connected to the output terminals.

When the light signal is ON, both of the MOSFETs 70 turn on, and become connected via the output terminals 30 to an external circuit including an electrical power supply and a load. On the other hand, when the light signal is OFF, both of the MOSFETs 70 turn off, and become shut off from the external circuit. Connection in common source configuration enables a linear output, and makes switching of the high frequency signal easier.

FIG. 4 is a graph (chart) illustrating transmission loss dependency of the photorelay on the frequency. The vertical scale is the transmission loss (dB), and the horizontal scale is the frequency (Hz). A thickness T1 of the prior art insulation board is 0.15 mm (relative permittivity: 4.9), in a comparative example. In the comparative example, the frequency at which the transmission loss increases 3 dB from 10 MHz is approximately 5 GHz, and hence the transmission loss is large.

In contrast, in the present embodiment where the thickness T1 of the insulation board is 0.3 mm (relative permittivity: 3.4), the frequency at which the transmission loss increases 3 dB is improved to approximately 13 GHz. Further, in the present embodiment where the thickness T1 of the insulation board is 0.6 mm (relative permittivity: 3.4), the frequency at which the transmission loss increases 3 dB is approximately 42 GHz. In other words, by setting the thickness T1 of the insulation board 10 at 0.3 mm or more and the relative permittivity at 3.4 or less, the transmission loss at a frequency higher than 5 GHz is reduced to 3 dB or less. Thereby, characteristics of the semiconductor devices and the like including the high speed DRAM are readily measured with a high degree of accuracy.

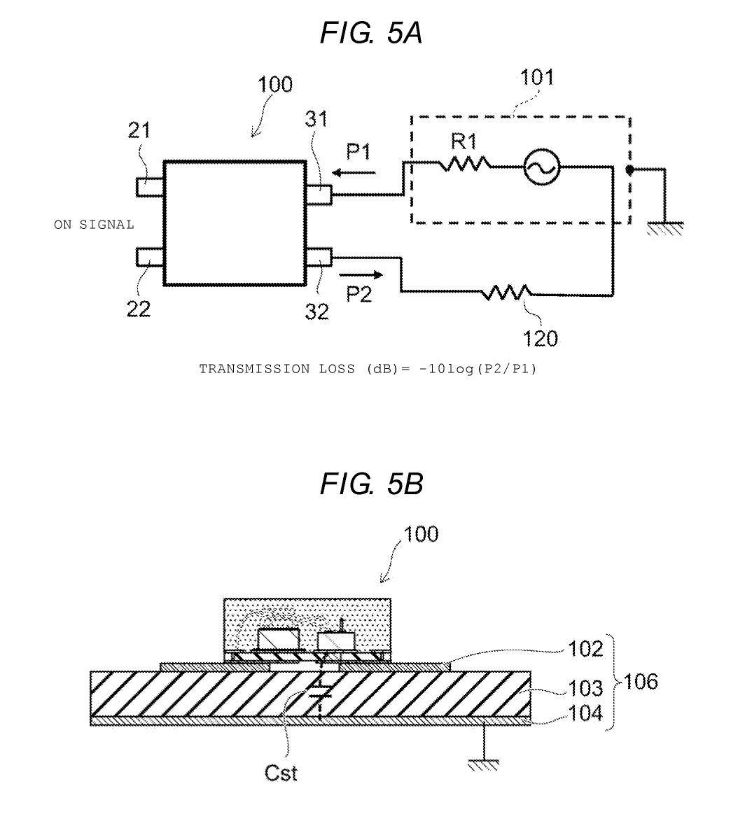

FIG. 5A illustrates one example of a diagram of a measurement circuit for measuring the transmission loss. FIG. 5B illustrates a schematic cross-sectional view of the measurement circuit in a state attached to an external circuit board. For example, the light emitting element such as an LED turns on by an input electrical signal, the MOSFETs turn on to flow the high frequency signal from a high frequency signal source 101 to a load 120. If the MOSFETs are of the vertical type, the back surface side of the chip may be a drain electrode. Thereby, a parasitic (stray) capacitance Cst is generated between the MOSFETs and a ground electrode 104 of the external circuit board 106, which are adjacent to each other. As the frequency increases, the high frequency signal component leaking to the parasitic capacitance Cst increases, which results in the increase of the transmission loss.

The output terminals 31, 32 of the photorelay correspond to terminals of a relay. The transmission loss thereof means insertion loss of the relay at the time of switching on. For example, where the input power is P1 and the output power is P2, the transmission loss is expressed by the following equation.

Transmission Loss(dB)=−10 log(P2/P1)

Note that transmission of the high frequency signal to the output terminals 31, 32 of the photorelay is achieved, for example, by making the wiring member 102 of the external circuit board 106 in the form of a microstripline or the like. In this case, the ground electrode 104 is often on the back surface side of the external circuit board (built into a tester device or the like) 106. Also, when a coplanar line is used, the ground electrode is provided on the front surface as well. In any case, the parasitic capacitance Cst is generated between the MOSFETs and the external circuit board 106.

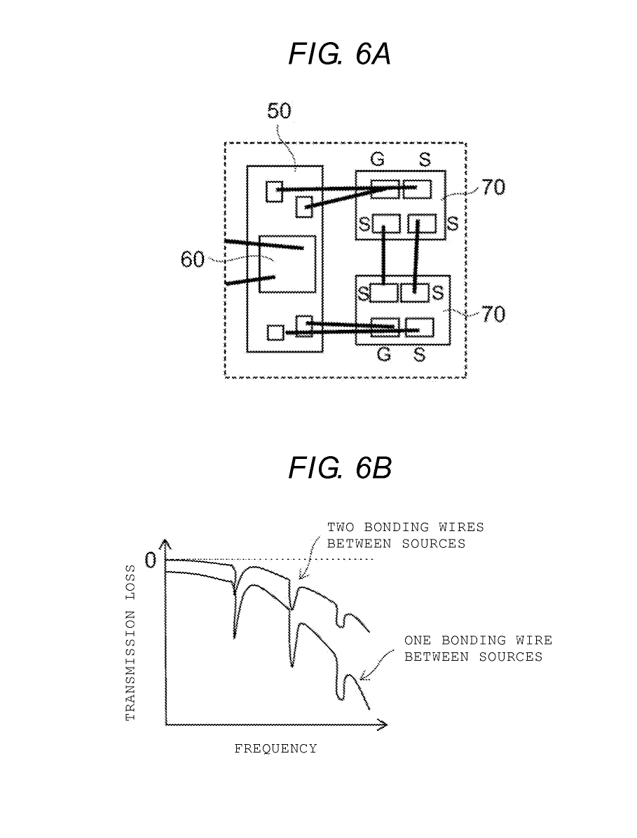

FIG. 6A is a partial schematic plan view of the photorelay according to a variant example of the first embodiment. FIG. 6B is a graph chart illustrating the transmission loss dependency of the photorelay on the frequency. The two MOSFETs 70 are connected in common source configuration, and supply a high frequency signal to the load in an ON state. For example, as illustrated in FIG. 6A, the source inductance is reduced by increasing the number of bonding wire connecting between two source electrodes S to two. Also, the source inductance is further reduced by arranging the two bonding wires non-parallel to one another. Further, a wire inductance is reduced by making the diameter of the bonding wire of the MOSFETs 70 side be larger than the diameter of the bonding wire of the light emitting element 60 side. As a result, the transmission loss is reduced.

For example, in the configuration diagram illustrated in FIG. 3, a ground inductance of the MOSFETs 70 in an ON state is reduced, which results in the improved gain. Thereby, as illustrated in FIG. 6B, the transmission loss is reduced.

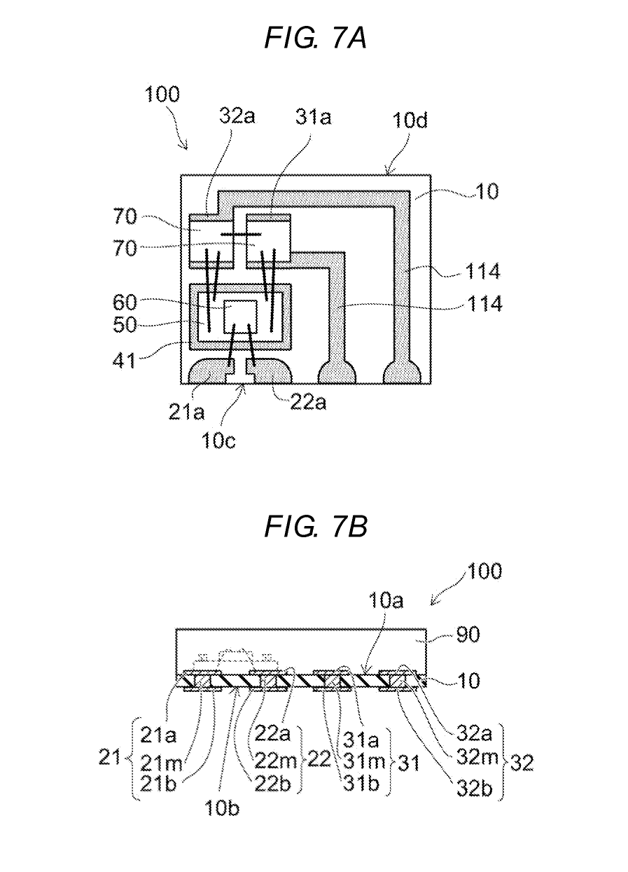

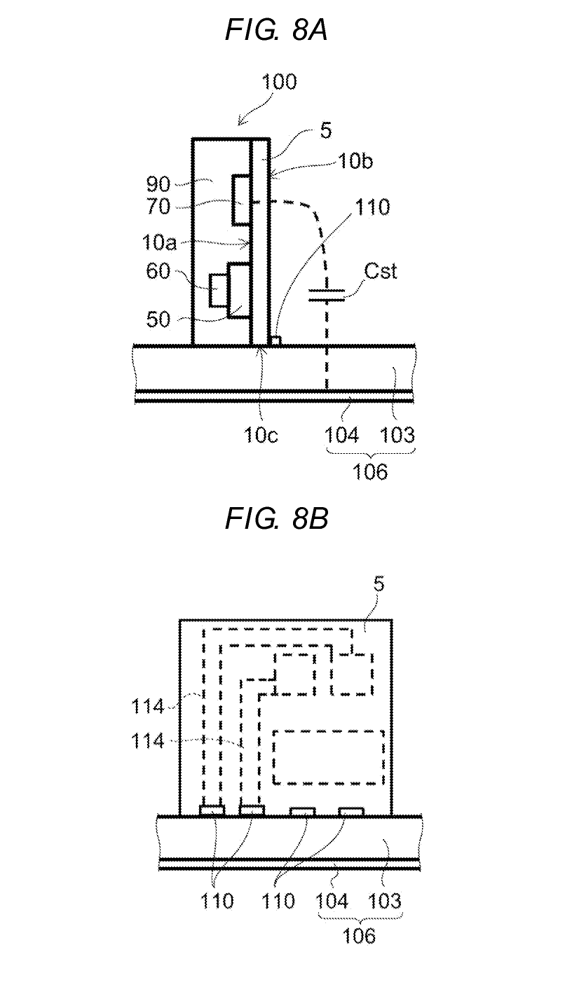

FIG. 7A is a schematic plan view of a photorelay according to a second embodiment. FIG. 7B is a schematic side view of the photorelay according to the second embodiment. The parasitic capacitance between the ground electrode of the external circuit board and the MOSFETs is reduced by disposing the input terminals 21, 22 and the output terminals 31, 32 on the same side surface, and by bonding the side surface of the photorelay 100 to an external circuit board (FIGS. 8A and 8B).

The photorelay 100 includes an insulation board 10, input terminals 21, 22, output terminals 31, 32, a die pad portion 41, a light receiving element 50, a light emitting element 60, MOSFETs 70, and a sealing resin layer 90. The insulation board 10 includes a first surface 10a, and an opposed second surface 10b spaced from and facing away from the first surface 10a. The input terminals 21, 22 include first conductive regions 21a, 22a on the first surface 10a. The output terminals 31, 32 include first conductive regions 31a, 32a on the first surface 10a. The die pad portion 41 is provided on the first surface 10a between the input terminals 21, 22 and the output terminals 31, 32.

The light receiving element 50 is bonded on the die pad portion 41. The light emitting element 60 is bonded on the top surface of the light receiving element 50, and is connected to the first conductive regions 21a, 22a of the input terminals 21, 22. The MOSFETs 70 are connected to the first conductive regions 31a, 32a of the output terminals 31, 32. The sealing resin layer 90 covers the light receiving element 50, the light emitting element 60, the MOSFETs 70, and the first surface 10a.

Extraction conductive regions are included either in the input terminals 21, 22, or in the output terminals 31, 32. In the present drawings, the extraction conductive regions 114 are provided as an extending portion of the output terminals 31, 32.

The attachment conductive regions 21m, 22m of the input terminals 21, 22 and the attachment conductive regions 31m, 32m of the output terminals 31, 32 extend on the first surface 10a to the first side surface 10c of the insulation board 10, which serves as the attachment surface of the insulation board 10 to another structure such as an external circuit board.

FIG. 8A is a schematic side view of the photorelay according to the second embodiment of FIGS. 7A and 7B, attached to an external circuit board having a ground electrode 104 on the non-mounting side thereof. FIG. 8B is a schematic back view of the photorelay according to the second embodiment attached to the external circuit board 106. The attachment conductive regions are each provided on the first side surface 10c. The first side surface 10c and wiring members (not illustrated) provided on the surface of the external circuit board 106 are joined by a solder material 110 (or conductive bonding material) so as to be in parallel with each other. Further, the joint strength is further enhanced by providing the second conductive region (not illustrated) on the second surface 10b of the insulation board 10 as well, and by joining the second conductive region with the solder material (or conductive bonding material) 110.

In this manner, the electrical connection becomes easy, and it is possible to dispose the back surfaces of the MOSFETs 70 normal to the external circuit board 106. The sealing resin layer 90 fixes the photorelay to the external circuit board 106 in a stable manner. Since the distance between the back surfaces of the MOSFETs 70 and the ground electrode 104 of the external circuit board 106 may be larger than the distance (thickness T1 of the insulation board 10) in the first embodiment, parasitic capacitance Cst therebetween is further reduced.

Also, the attachment conductive regions 21m, 22m, 31m, 32m may be provided on the inner walls of cutout portions extending into the first side surface 10c of the insulation board 10. By so extending the conductive regions, face to face contact between the conductive regions 21m, 22m, 31m, 32m and conductive traces, solder bumps, or similar conductive areas (not shown) on the external circuit board can be established, and the surface area of contact therebetween increased.

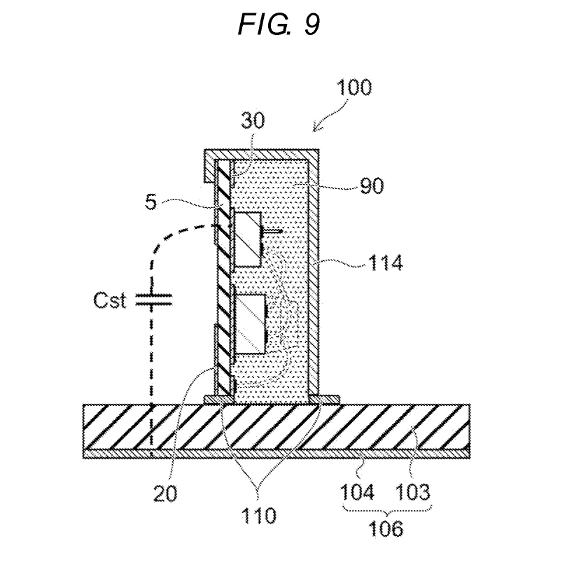

FIG. 9 is a schematic cross-sectional view of a photorelay according to a third embodiment, which is attached to the external circuit board 106. The extraction conductive regions 114 of the output terminals 30 are extended to the first side surface 10c where the attachment conductive regions of the input terminals 20 are provided, through the sealing resin layer 90. Since the side surfaces of the sealing resin layer 90 are provided on the first side surface 10c, the external circuit board 106 is attached in a stable state.

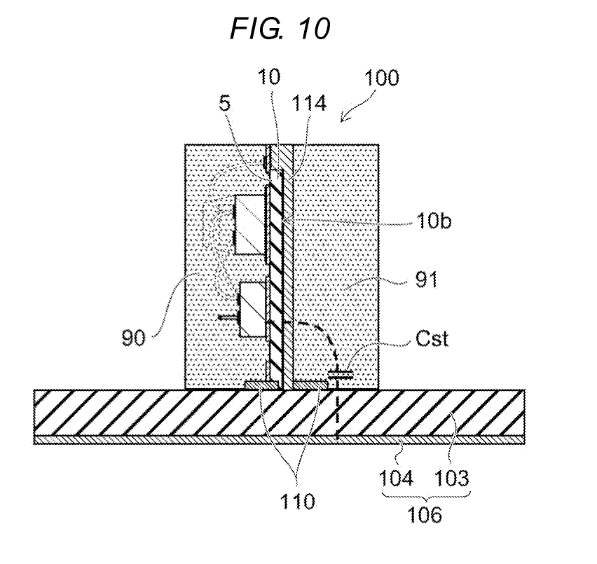

FIG. 10 is a schematic cross-sectional view of a photorelay according to a fourth embodiment, which is attached to the external circuit board. The extraction conductive regions 114 of the input terminals 21, 22 are extended on the second surface 10b of the insulation board 10 of the photorelay 100, up to the side where the input terminals 21, 22 are present. Solder or a conductive joining material 110 is located between and in electrical contact with both the extraction conductive regions of the first conductive regions, and with the second conductive regions, of terminals 21, 22, 31 and 32. In addition, by providing a second sealing resin layer 91 on the extraction conductive regions 114, the photorelay is attached more securely on the external circuit board 106.

The photorelays 100 according to the first to fourth embodiments may reduce the transmission loss. Thereby, the high frequency characteristics of semiconductor devices including DRAM are measured with a high degree of accuracy and at a high speed. Also, these photorelays are readily reduced in size and thickness, and are suitable for mass production. In addition, adhesion between the sealing resin layer 90 and the mounting member 5 is enhanced to improve the moisture resistance. Thereby, high reliability is maintained even in a high temperature and high humidity environment.

These photorelays are widely used in industrial instruments including semiconductor testers for testing ICs and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photorelay, comprising:
an insulation board including a first surface, and a second surface opposed to and facing away from the first surface;
an input terminal including a first conductive region on the first surface;
an output terminal including a first conductive region on the first surface;
a die pad portion provided on the first surface between the input terminal and the output terminal;
a light receiving element connected to the die pad portion;
a light emitting element connected to an exposed surface of the light receiving element and connected to the first conductive region of the input terminal;
a MOSFET connected to the first conductive region of the output terminal; and
a first sealing resin layer covering the light receiving element, the light emitting element, the MOSFET, and the first surface, wherein
a connecting electrode is included as a portion of either the input terminal or the output terminal, and
an attachment conductive region as a part of the input terminal and an attachment conductive region as a part of the output terminal are provided on a side surface of the insulation board extending between the first and second surfaces thereof.

2. The photorelay according to claim 1, wherein
the input terminal includes a second conductive region on the second surface, and
the output terminal includes a second conductive region on the second surface.

3. The photorelay according to claim 2, wherein
a cutout portion forming a recessed wall extends inwardly of the side surface of the insulation board, and
the attachment conductive region of the input terminal and the attachment conductive region of the output terminal are each provided on the recessed wall.

4. The photorelay according to claim 1, wherein
the extraction conductive region of the input terminal is provided on one of an exposed surface of the insulation board or with the first sealing resin layer.

5. The photorelay according to claim 1, wherein
the extraction conductive region of the output terminal is provided on one of an exposed surface of the insulation board or within the first sealing resin layer.

6. The photorelay according to claim 1, further comprising:
a second sealing resin layer provided on the second surface, wherein
the extraction conductive region is provided on the second surface, and
the second sealing resin layer covers the second surface and the extraction electrode.

7. The photorelay of claim 1, wherein the light receiving element is connected to the die pad portion with an adhesive.

8. The photorelay of claim 1, wherein the light receiving element is connected to the die pad portion with a conductive adhesive.

9. A photorelay device configured for electrical connection of the electrical contacts thereof to electrical contacts on a wiring board and physical attachment of the photorelay device to the wiring board, comprising:
an insulation board including at least a first side, a second side, and a side surface extending between the first side and the second side;
a first conductor and a second conductor extending along the side surface and the first side, the second conductor extending further along the first side than the first conductor, and a first conductive region separated from, and located between, the first conductor and the second conductor;
a light receiving element electrically connected to the first conductive region and having an exposed side thereof, in a portion of which light may be detected;
a light emitting element overlying the exposed surface and sealingly covering, against the admission of outside light, the portion of the exposed surface at which light may be detected;
at least one electrical connection between the first conductor and the light emitting element;
a MOSFET electrically connected to the second conductor; and
at least two electrical connections between the MOSFET and the light emitting element.

10. The photorelay of claim 9, further comprising a third conductor extending along the side surface and along the first surface from the side surface and a fourth conductor extending along the side surface and the first surface, the fourth conductor extending further along the first surface from the side surface the first conductor and the third conductor; and
the first conductive region located between end portions of the second conductor and the fourth conductor.

11. The photorelay of claim 10, further comprising a second MOSFET connected to the end of the fourth conductor, and electrically connected to the light receiving element.

12. The photorelay of claim 11, wherein the electrical connection between the light receiving element and at least one of the MOSFET and the second MOSFET includes at least two independent connections.

13. The photorelay of claim 12, wherein the MOSFET and the second MOSFET are electrically interconnected by at least one wired connection therebetween.

14. The photorelay of claim 10, wherein the third conductor and the light emitting element are electrically connected.

15. The photorelay of claim 9, further comprising a first second side conductor extending along the second side from the side surface and electrically connected to the first conductor along the side surface; and
wherein, upon connection of the side surface of the insulation board to a wiring board such that the first and second surfaces of the insulation board extend away from the wiring board, and electrical interconnection may be established between conductive elements on the wiring board and the first conductor and first second side conductor.

16. The photorelay of claim 9, wherein, upon connection of the side surface of the insulation board to a wiring board such that the first and second surfaces of the insulation board extend away from the wiring board, an electrical interconnection may be established between separate conductive elements on the wiring board and the first conductor and the second conductor.

17. A photorelay comprising:
an insulation board having a first surface, a first side surface, and a second side surface opposite to the first side surface, the insulation board having a thickness of 0.3 mm or more between the first side surface and the second side surface and a relative permittivity of 3.4 or less;
an input terminal including a first conductive region on the first surface, and provided on the first side surface;
a die pad portion provided on the first surface;
an output terminal including a first conductive region on the first surface in an area that is adjacent to the die pad portion on a side thereof opposite to the input terminal, a portion of the output terminal provided on the second side surface;
a light receiving element bonded on the die pad portion;
a light emitting element bonded on an exposed surface of the light receiving element and connected to the first conductive region of the input terminal;
a MOSFET connected to the first conductive region of the output terminal; and
a sealing resin layer covering the light receiving element, the light emitting element, the MOSFET, and the first surface.

18. The photorelay of claim 17, wherein the MOSFET is electrically connected to the light receiving element.

19. The photorelay of claim 17, further comprising:
a second input terminal including a first conductive region on the first surface, and provided on the first side surface; and
a second output terminal including a first conductive region on the first surface in an area that is adjacent to the die pad portion on a side thereof opposite to the input terminal, a portion of the output terminal provided on the second side surface;

20. The photorelay of claim 19, further including a second MOSFET electrically connected to the second output terminal, the light receiving element including a photodiode array having an anode and a cathode, wherein the gates of the MOSFET and the second MOSFET are each electrically connected to the anode of the photodiode, the sources of the MOSFET and the second MOSFET are each connected to the cathode of the photodiode, and the drain of the MOSFET is connected to the output terminal and the drain of the second MOSFET is connected to the second output terminal.
